(19) United States
(12) Patent Application Publication
(10) Pub. No.: US 2008/0012153 A1
(43) Pub. Date: Jan. 17, 2008

(54) Direct drive technology chip package

(75) Inventor: Chih Wen Cheng, Zhubei (TW)

Correspondence Address: BACON & THOMAS, PLLC, 625 SLATERS LANE, FOURTH FLOOR, ALEXANDRIA, VA, 22314, US

(73) Assignee: DDTIC Corporation, Ltd., Zhubei City (TW)

(21) Appl. No.: 11/656,990

(22) Filed: Jan. 24, 2007

(30) Foreign Application Priority Data
Jul. 13, 2006 (TW) 095212297

(51) Int. Cl. H01L 23/28

(52) U.S. Cl. 257/787

(57) ABSTRACT

A chip package that can be directly used by users, on one end of the chip package is provided a plurality of metal terminals that can be connected to electronic equipment directly, such as computer. A vertical hole in communication with a chip substrate or a protection circuit board inside the chip package can be formed on the chip package, and by inserting resistors with different resistances (or other electronic members) in the vertical hole, it can micro-adjust the electronic characteristic of the chip or improve the protection ability of the protection circuit board.

### FIELD OF THE INVENTION

The present invention relates to a design of a chip package structure, and more particularly to a direct drive technology chip package.

### BACKGROUND OF THE INVENTION

Currently, there are various chip package types, such as: TSOP, SO8, BGA, DIP, PLCC, CQFP, DMP and etc. However, all these chips cannot be used directly by consumer, since they must be processed by a professional electronic engineer who will design electric circuit, make a layout, and then produce a circuit board, and then the chips have to be processed with high-cost equipments in SMT (surface mounting technology) factory to solder the various components of the electric circuit to the circuit board. While the processing procedure is complicated and the cost is high, the electronic products produced are not qualified in terms of high-temperature resistance, waterproof, dustproof, and impact resistance properties (for example, the plastic case will be melt when subjected to a high temperature, or many electronic components can not operate when the temperature is too low), and they can only be repaired by professionals with special equipment.

The present invention has arisen to mitigate and/or obviate the afore-described disadvantages.

### SUMMARY OF THE INVENTION

The primary objective of the present invention is to provide a chip package that can be directly used by users, on one end of the chip package is provided a plurality of metal terminals that can be connected to an electronic equipment directly, such as computer. A vertical hole in communication with a chip substrate or a protection circuit board inside the chip package can be formed on the chip package, and by inserting resistors with different resistances (or other electronic components) in the vertical hole, it can micro-adjust the electronic characteristic of the chip or to improve the protection ability of the protection circuit board.

Since the chip package can be directly inserted in the computer (or other electronic instruments) and has the improved performances in respects of high-temperature resistance, waterproof, dustproof, and impact resistance properties, in case of a failure, the user can replace the chip package directly by himself, therefore, chip package is very convenient to use.

### BRIEF DESCRIPTION OF THE DRAWINGS

FIG. 1 is a perspective view in accordance with the present invention for showing a chip package after chip bonding and wire bonding processes;

FIG. 2 is a perspective view of the chip package in accordance with the present invention; and

FIG. 3 is a perspective view of a chip package in accordance with another embodiment of the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

Firstly, the method of manufacturing the chip package in accordance with the present invention is described. The manufacturing processes for a chip comprise: wafer dicing, chip bonding, wire bonding, encapsulating, lead forming, plating, punching, mold pressing, and stamping. The step of lead forming is the focus of attention of the present invention.

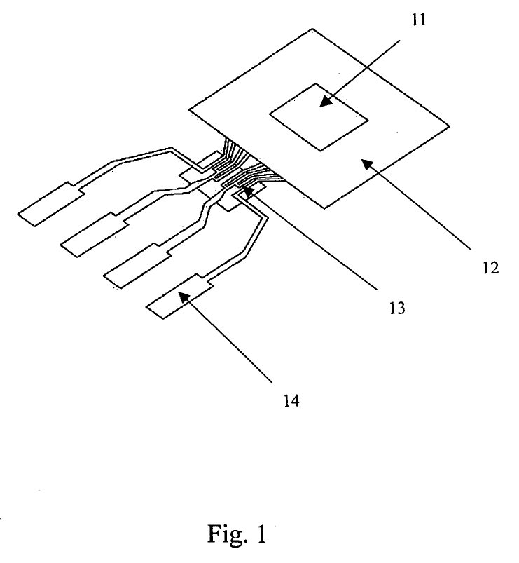

As shown in FIG. 1, which shows the result of the chip bonding process and the wire bonding process, wherein the chip 11 is formed on the chip substrate 12, a plurality of metal wires 14 passes through a circuit board 13 and then extends left. And then the encapsulating process is carried out to form a chip package 1 by pouring colloid substance on the chip 1.

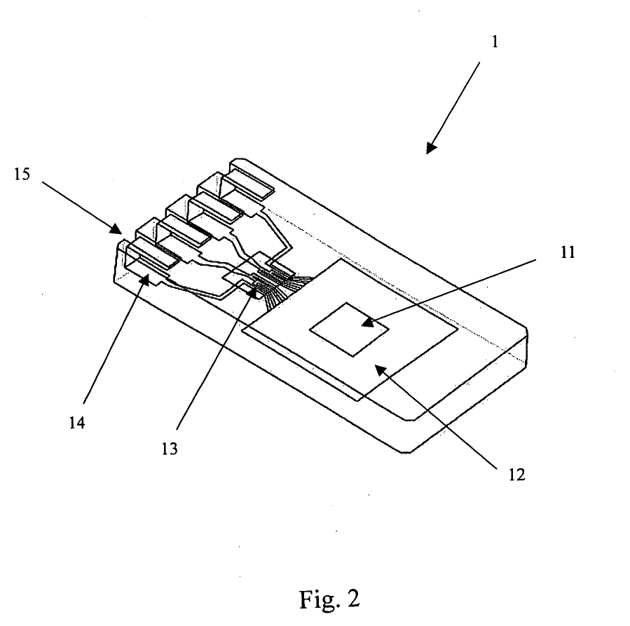

Referring to FIG. 2, a plurality of grooves 15 is molded in the top left of the chip package 1, and finally the metal wires 14 extending out of the chip package 1 are attached to the grooves 15 by mold pressing, thus forming terminals that can be connected to electronic instruments directly, such as computer, this is the so-called direct drive technology chip package (DDTIC). The chip package of the present invention can be made into various types, such as: USB, SD, SATA, RJ45.

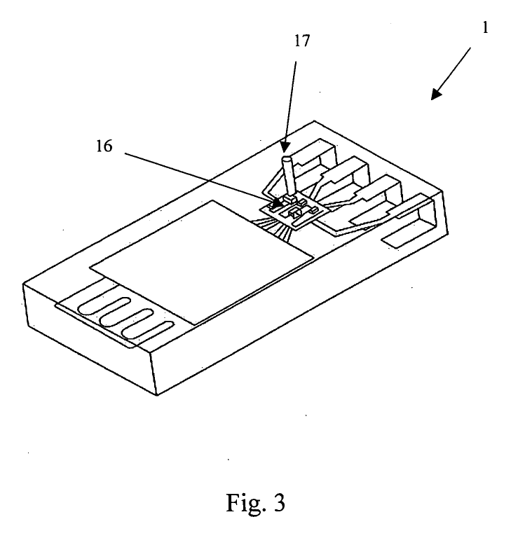

FIG. 3 shows another embodiment of the present invention, wherein a vertical hole 16 in communication with the chip substrate 12 or the protection circuit board 13 can be formed at an appropriate position on the chip package 1. When it is necessary to micro-adjust the electronic characteristic of the chip or to improve the protection ability of the protection circuit board 13, a resistor 17 (or a capacitor) can be inserted in the vertical hole 16.

While we have shown and described various embodiments in accordance with the present invention, it is clear to those skilled in the art that further embodiments may be made without departing from the scope of the present invention.

What is claimed is:

1. A direct drive technology chip package, comprising a plurality of metal wires extending out of the chip package after encapsulation process, a plurality of grooves formed on the chip package adjacent to the metal wires, the metal wires being attached to the grooves by molding pressing, thus forming a plurality of metal terminals to be able to connect directly with an electronic instrument, such as a computer.

2. The direct drive technology chip package as claimed in claim 1, wherein a vertical hole in communication with a chip substrate or a protection circuit board inside the chip package is formed on the chip package, when it is necessary to micro-adjust electronic characteristic of the chip or to improve protection ability of the protection circuit board, a resistor or a capacitor can be inserted in the vertical hole so as to be connected to the chip substrate or the protection circuit board inside the chip package for micro-adjusting the electronic characteristic of the chip or to improve the protection ability of the protection circuit board.
